(19) United States
(12) Patent Application Publication
(10) Pub. No.: US 2012/0138354 A1
(43) Pub. Date: Jun. 7, 2012

(54) Method of preparing conductive gaskets on a chassis, the chassis with conductive gaskets, and method of assembling an electric device including the same

(75) Inventor: Wen-Cheng Lin, Taoyuan Shien (TW)

(73) Assignee: Quanta Computer Inc., Taoyuan Shien (TW)

(21) Appl. No.: 13/064,760

(22) Filed: Apr. 13, 2011

(30) Foreign Application Priority Data
Dec. 2, 2010 (TW) 099141959

(51) Int. Cl. H05K 9/00; B32B 38/00; H05K 3/00

(52) U.S. Cl. 174/358; 29/829; 156/280; 156/150

(57) ABSTRACT

A method of preparing conductive gaskets on a chassis includes steps as follows. A chassis is provided. An elastomer is pasted on an inner surface of the chassis. A conductive film is formed to cover both the inner surface of the chassis and the elastomer. The chassis with conductive gaskets, and a method of assembling an electric device including the same are also provided in the invention.

### RELATED APPLICATIONS

This application claims priority to Taiwanese Application Serial Number 099141959, filed Dec. 2, 2010, which is herein incorporated by reference.

### BACKGROUND

1. Technical Field

The present invention relates to a protection component from Electromagnetic Interference (EMI) and Electrostatic discharge (ESD), more particular to a method of preparing conductive gaskets on a chassis.

2. Description of Related Art

At present, in order to reduce impacts from Electromagnetic Interference (EMI) and Electrostatic Discharge (ESD) inside a computer, a traditional way is to install a certain quantity of conductive foams in a chassis of the computer.

In details, each of the conductive foams is prepared by wrapping an electrically conductive tape on a sponge; next, the conductive foams are fixed in the chassis. Thus, once the conductive foams are contacted with the electrical components in the chassis, the conductive foams not only provide with metallic shielding on the electrical components, but also conduct the electromagnetic signals to a ground.

However, the mentioned steps of wrapping the conductive tape on the sponge and installing the conductive foams inside the chassis need to spend extra labor and manufacturing costs. Moreover, because the conductive foams are installed in different positions in the chassis, the conductive foams are different in types, models, prices, and even from different suppliers depends on the positions. Therefore, makers need to weigh the inventory and cost of the conductive foams before preparing and purchasing the conductive foams, such that to further cause much more manpower and cost.

Further, if the electrically conductive tape is defected, the conductive capability of the conductive foam will be degraded, and further to weaken the performance of the computer preventing from Electromagnetic Interference (EMI) and Electrostatic Discharge (ESD).

### SUMMARY

The present invention is to disclose a method of preparing conductive gaskets on a chassis and a method of assembling an electric device. By simplifying the manufacturing process, the present invention can decrease manpower and costs for preparing and purchasing the conductive foams mentioned in prior art.

In practice of the present invention, the method of preparing conductive gaskets on a chassis comprises steps as follows. First, providing a chassis having an inner surface thereon; then, pasting or fixing an elastic block on the inner surface of the chassis; next, forming a conductive film on the inner surface of the chassis in which the conductive film is overlaid on both the elastic block and the inner surface of the chassis.

In one embodiment of the present invention, the step of forming the conductive film on the inner surface of the chassis further comprises a step of by an electroplating means, depositing a plurality of metal ions with conductive properties on surfaces of the elastic block and the inner surface of the chassis so as to integrate into the conductive film.

In one variation of the embodiment, the metal ions are deposited on the surfaces of the elastic block which are not contacted the inner surface of the chassis.

In another variation of the embodiment, the metal ions are deposited on all surface of the elastic block in which some of the metal ions penetrate through the elastic block to dispose on a section of the inner surface which is contacted by the elastic block.

In the embodiment, the electroplating means can be an electroplating method of plastic plating, vacuum plating, composite plating electroless plating, spray plating, immersion plating or plasma plating.

Also, in the embodiment, the material of the conductive film can be aluminum, nickel, copper, chromium, tin, titanium, stainless steel and the combination thereof.

In another embodiment of the present invention, the step of forming the conductive film on the inner surface of the chassis further comprises a step of by a sputtering deposition means, depositing a plurality of metal ions with conductive properties on surfaces of the elastic block and the inner surface of the chassis so as to integrate into the conductive film.

In the present invention, the elastic block can be made of plastic, rubber, cloth, leather or paper. Besides, a compression ratio of the elastic block is in a range of 20%-30%.

Furthermore, in practice of the present invention, the method of assembling an electric device comprises steps as follows. First, providing a first chassis; next, pasting or fixing an elastic block on an inner surface of the first chassis; then, depositing to coat a conductive film on the inner surface of the first chassis in which the conductive film is overlaid on both the elastic block and the inner surface of the first chassis; next, providing a second chassis and a motherboard in which the motherboard is with a component thereon; and assembling the first chassis and the second chassis together in which the motherboard is sandwiched between the first chassis and the second chassis, and an section of the conductive film corresponding to the elastic block contacts with a grounding portion of the component, and the conductive film is electrically conducted to a grounding of the electric device.

Also, the present invention further is to disclose a chassis with conductive gaskets, in which by integrally forming a conductive film on the chassis so as to unify the conductive capability of the conductive film, the present invention can reduce the possibility that a computer is harmed by Electromagnetic Interference (EMI) and Electrostatic Discharge (ESD).

The present invention is to disclose a chassis with conductive gaskets in which by integrally forming a conductive film to be overlaid on the chassis, the conductive film can veil some elastic blocks therein so as to enhance the artistic appearance of the chassis.

In one embodiment of the present invention, the chassis with conductive gaskets, comprises a casing, a conductive film, and at least one elastic block. The casing is with an inner surface thereon. The conductive film is overlaid on the inner surface of the casing, and is with at least one bulge portion thereon. The elastic block is disposed on the inner surface of the casing, covered by the bulge portion, and has a same shape with the bulge portion.

In one variation of the embodiment, the bulge portion of the conductive film covers the surfaces of the elastic block which are not contacted with the inner surface of the casing.

In another variation of the embodiment, the bulge portion of the conductive film covers all surfaces of the elastic block.

In the present invention, the elastic block can be made of plastic, rubber, cloth, leather or paper. Besides, a compression ratio of the elastic block is in a range of 20%-30%.

Also, in the embodiment, the material of the conductive film can be aluminum, nickel, copper, chromium, tin, titanium, stainless steel and the combination thereof.

As mentioned above, in the present invention, by forming a conductive film to cover the elastic block on the chassis, the maker can make decisions not to adopt the prior art of the conductive foams for EMI/ESD shielding so as to simplify the manufacturing process, such as omitting the complicated processes of preparation and purchase of the conductive foams, and to further save manpower and costs.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a flow chart of a method of preparing conductive gaskets on a chassis according to one embodiment of the present invention.

FIG. 2(a) to FIG. 2(d) are flow diagrams with a section view of the chassis therein showing the sequential operations according to step (101) to step (103) of FIG. 1 respectively in one variation of the embodiment in FIG. 1.

FIG. 3(a) to FIG. 3(b) are flow diagrams with a section view of the chassis therein showing the sequential operations according to step (103) of FIG. 1 in another variation of the embodiment in FIG. 1.

FIG. 4 is a flow chart showing a method of assembling an electric device according to one embodiment of the present invention.

FIG. 5 is a sectional schematic view of the electric device according to the other embodiment of the present invention.

### DESCRIPTION OF THE PREFERRED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

In the traditional manufacturing process mentioned above, since the conductive foam needs to be made by wrapping electrically conductive tape on the sponge before being fixed in the chassis, the present invention substitutes the known conductive foams with an elastic block fixed on an inner surface of a chassis, and directly coats a conductive film to cover both the elastic block and the inner surface of the chassis, so that the present invention simplifies the traditional manufacturing process, but still can prevent from being harmed by Electromagnetic Interference (EMI) and Electrostatic Discharge (ESD).

Also, the conductive film of the present invention can be not only a shield element, but also can be a buffer by contacting and pressing an element so as to guide electromagnetic waves generated from the element (or from outside the chassis) to ground. Besides, by coating a conductive film on the chassis, the elastic block can be veiled in the conductive film integrally so as to enhance the artistic appearance of the chassis.

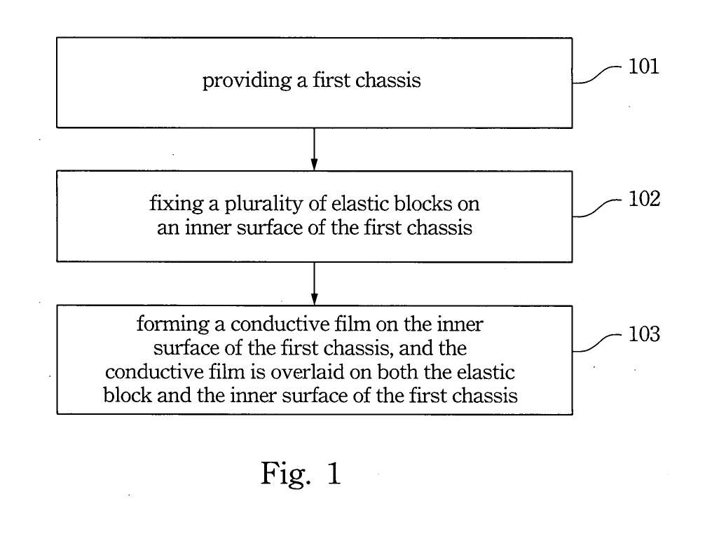

Refer to FIG. 1. FIG. 1 is a flow chart of a method of preparing conductive gaskets on a chassis according to one embodiment of the present invention.

In practice of the present invention, the method of preparing conductive gaskets on a chassis mainly at least comprises steps as following:

Step (101): providing a first chassis.

Step (102): fixing a plurality of elastic blocks on an inner surface of the first chassis.

Step (103): coating a conductive film on the inner surface of the first chassis, and the conductive film is overlaid on both the elastic block and the inner surface of the first chassis.

Therefore, comparing to the conductive foam of the traditional manufacturing process which needs to be prepared preliminary before being fixed on the chassis, the present invention directly forms a conductive film to cover both the inner surface of the first chassis and the elastic block, so as to simplify the traditional manufacturing process.

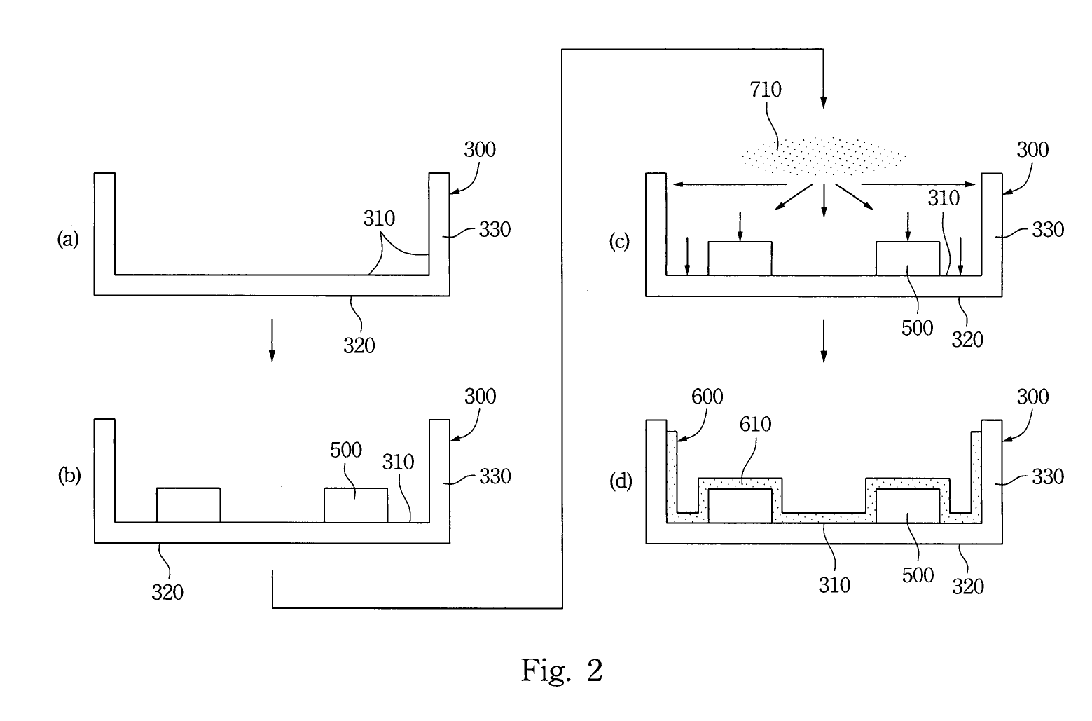

Refer to FIG. 2(a) to FIG. 2(d). FIG. 2(a) to FIG. 2(d) are flow diagrams with a section view of the chassis therein showing the sequential operations according to step (101) to step (103) of FIG. 1 respectively in one variation of the embodiment in FIG. 1.

Refer to FIG. 2(a), firstly, the embodiment in step (101) is to obtain a first chassis 300. The first chassis 300 includes a casing 330 at least having an outer surface 320 and an inner surface 310 thereon. The inner surface 310 in this step is not yet with any metal coating layer.

The first chassis 300, for example, can be made by injection molding, but not limited in manufacturing methods. Also, the material of the first chassis 300 is not limited either, for example, high density polyethylene (HDPE), Polypropylene (PP), Acrylonitrile Butadiene Styrene (ABS), NYLON or the combination thereof.

Refer to FIG. 2(b) next, the embodiment in step (102) is to obtain some elastic blocks 500, then, to fix the elastic blocks 500 on the inner surface 310 of the first chassis 300. For example, by applying an adhesive (not shown in the figures) on the inner surface 310 of the first chassis 300, one surface of each elastic block 500 can be pasted on the inner surface 310 of the first chassis 300.

While obtaining the elastic blocks 500 in step (102), the material of the elastic blocks 500 in the present invention is not limited. For example, the elastic blocks 500 can be made of plastic, rubber, cloth, leather or paper. Besides, an elastic blocks 500 having a compression ratio in a range of 20%-30% of its volume is preferably.

Refer to FIG. 2(c) and FIG. 2(d). In step (103), specifically, by an electroplating means or by a sputtering means for coating, the embodiment is to proceed by depositing a plurality of metal ions 710 with conductive properties on surfaces of the elastic blocks 500 and the inner surface 310 of the first chassis 300. Thus, the metal ions 710 can be integrated into a conductive film 600. The conductive film 600 can be designed to electrically connect with a ground, and anyone having ordinary skills in the art of the present invention will be familiar to electrically connect the conductive film 600 with a ground by any forms, thus, it will not be discussed here.

Regarding to the electroplating means, the present invention is not limited in any kinds of the electroplating means, for example, the electroplating means can be one of plastic-plating, vacuum-plating, composite plating electroless plating, spray plating, immersion plating or plasma plating.

In one of the variations, for example on the vacuum plating, since each of the elastic blocks 500 is pasted to contact with (or cover) the inner surface 310 of the first chassis 300 with one surface thereof, the metal ions 710 are deposited on other surfaces of the elastic blocks 500 not contacting with (or covering) the inner surface 310 of the first chassis 300, thus, After the vacuum plating process is finished, the metal ions 710 are integrated into the conductive film 600 covering both the inner surface 310 of the first chassis 300 and the surfaces of the elastic blocks 500 not contacting with (or covering) the inner surface 310 of the first chassis 300.

Consequently, since the metal ions 710 are deposited uniformly, each part of the conductive film 600 is equal in electrical conduction capability. Therefore, while setting the inner surface 310 of the first chassis 300 as grounding, the conductive film 600, covering the elastic blocks 500, can be played as grounding as well.

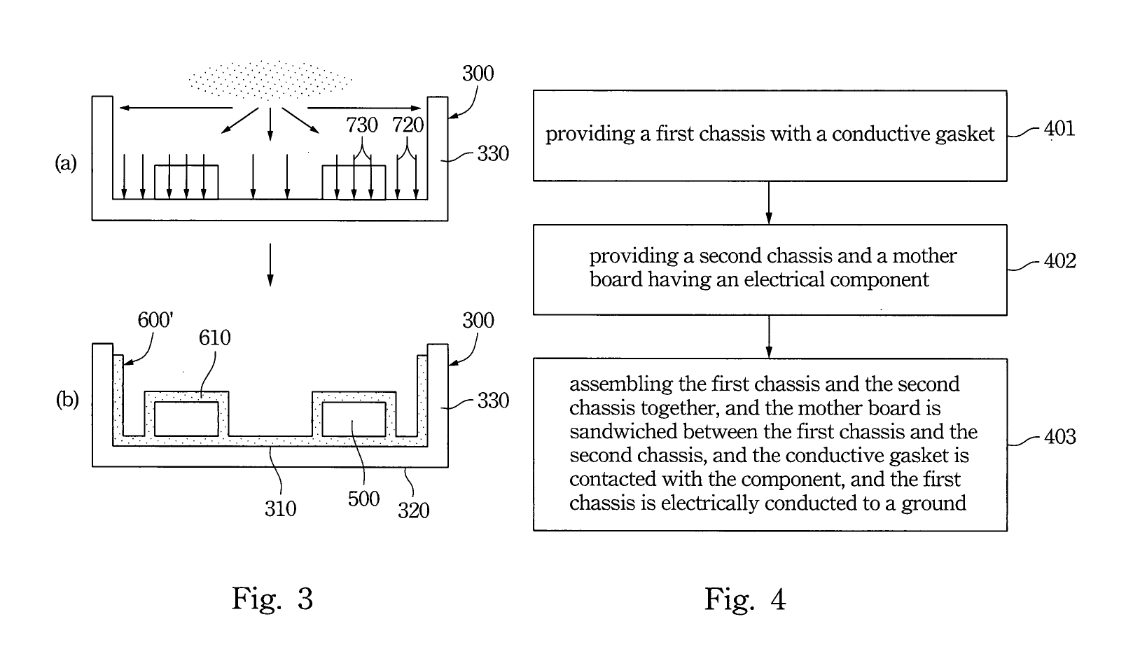

Refer to FIG. 3(a) to FIG. 3(b). FIG. 3(a) to FIG. 3(b) are flow diagrams with a section view of the chassis therein showing the sequential operations according to step (103) of FIG. 1 in another variation of the embodiment in FIG. 1.

In another of the variations, for example on the plasma plating, one part of the metal ions 720 are deposited on the inner surface 310 of the first chassis 300, another part of the metal ions 720 are deposited on the surfaces of the elastic blocks 500 not contacting with (or covering) the inner surface 310 of the first chassis 300, and the other part of the metal ions 730 are penetrated through the elastic blocks 500 to dispose on a section of the inner surface 310 which is contacted with (or covered) by the elastic blocks 500.

All of the metal ions 720 are integrated into an entire conductive film 600′ in which the conductive film 600′ covers all surfaces of the elastic blocks 500 (refer to FIG. 3(b)).

In another of the variations, since the conductive film 600′ also covers the surface of each elastic block 500 contacting with (or covering) the inner surface 310 of the first chassis 300, the conductive film 600′ further provides more conductive paths for EMI/ESD shielding comparing to the variation mentioned in FIG. 2.

Needed to know, since the metal ions 730 are tiny enough (e.g. nano-sized), the penetrated holes, generated the metal ions 730, of the elastic blocks 500 would not jeopardize the structure of the elastic blocks 500 so as to remain the elastic property of the elastic blocks 500.

While depositing by either the electroplating means or the sputtering deposition means, the conductive film 600, 600′ in the present invention is not limited in material, for example, can be adopted to be made of aluminum, nickel, copper, chromium, tin, titanium, stainless steel and the combination thereof.

Finally, refer to FIG. 2(d) again, the first chassis 300 which are processed by the mentioned steps, includes specifically a casing 330, a conductive film 600, and some elastic blocks 500. Since each elastic block 500 are located between the casing 330 and the conductive film 600, the sections of the conductive film 600 corresponding to the elastic blocks 500 can be respectively presented as a bulge portion 610 according to each elastic block 500 located beneath the conductive film 600. That is, each elastic block 500 is covered by the corresponding bulge portion 610, and respectively has a same shape with the corresponding bulge portion 610.

In other embodiment of the resent invention, the first chassis 300 can be implemented on a part of a shell of an electric device 200 such as hand held devices like a notebook, a mobile phone and a GPS device etc.

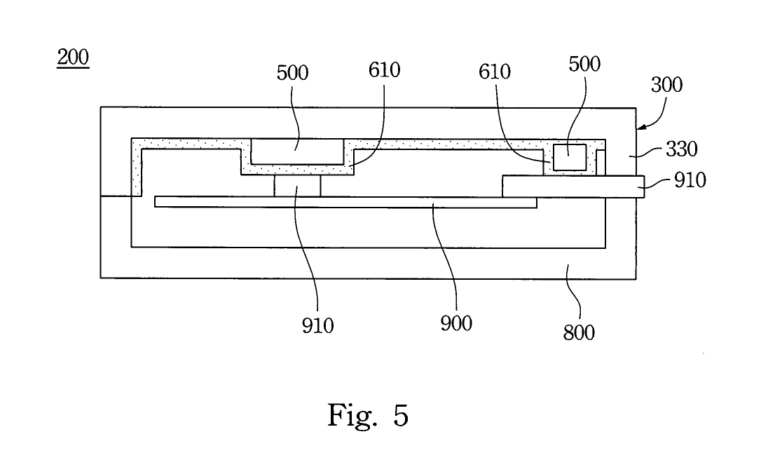

Refer to FIG. 4 and FIG. 5. FIG. 4 is a flow chart showing a method of assembling an electric device according to one embodiment of the present invention. FIG. 5 is a sectional schematic view of the electric device according to the other embodiment of the present invention.

A method of assembling the electric device 200 mainly at least comprises steps as following:

Step (401): providing a first chassis 300 as mentioned above (FIG. 2(d)).

Step (402): providing at least a second chassis 800 and at least a motherboard 900. The second chassis 800 is not limited to be the same with the first chassis 300 having the conductive film 600 and the bulge portion 610 as well. Refer to FIG. 5, the motherboard 900 can be provided with a component 910 (e.g. card reader or connector) thereon.

Step (403): assembling the first chassis 300 and the second chassis 800 together, so that the motherboard 900 is sandwiched between the first chassis 300 and the second chassis 800, and one of the bulge portion 610 (i.e. the conductive gasket) of the conductive film 600 contacts and presses grounding portion (e.g. a metal shell) of the component 910 so as to make sure that the bulge portion 610 of the conductive film 600 and the grounding portion of the component 910 can be electrically conducted with each other appropriately.

Besides, since the conductive film 600 is integral continuously to cover both the inner surface 310 of the first chassis 300 and the elastic blocks 500, every area of the conductive film 600 can be served as grounding. Therefore, by contacting and pressing the component 910 with the bulge portion 610 of the conductive film 600, the grounding portion of the component 910 can be extended to reach the coverage of the conductive film 600 so as to further reinforce the power of EMI/ESD shielding.

Anyone having ordinary skills in the art of the present invention will be familiar to electrically setting the inner surface 310 of the first chassis 300 covered by the conductive film 600 as grounding by any forms, so that the conductive film 600 including its bulge portions 610 connecting the inner surface 310 of the first chassis 300 become grounding. Here, it will not be discussed in details.

Thus, no matter the electromagnetic waves generated from inside or outside of the electric device 200, the electromagnetic waves can be guided by the bulge portions 610 via the conductive film 600 to grounding of the electric device 200 so as to easily eliminate noise signals or static signals.

Also, since the conductive film 600 is formed integrally, each area of the conductive film 600 is equal in electrical conduction capability, so as to reduce the possibility that the electric device 200 is harmed by EMI/ESD.

Needed to know that while obtaining the elastic blocks 500 in step (102), which could be collected from waste material, such as foams or resin sticks, around his/her manufacturing environment. Therefore, because the waste material for the elastic blocks 500 could be cheap or even, thus, manpower and costs of preparation and purchase of the conductive foams will be reduced.

Moreover, needed to know again, the attached drawings are only for illustration, the distribution of the elastic blocks 500 can be changed depending on different modal numbers or types, not limited to be arranged along the margin of the casing 330 as shown in FIG. 5 for contacting and pressing a metal shell or grounding of a connector. For example, the elastic blocks 500 else can be arranged inside of the inner surface 310 away from the margin thereof (FIG. 5)

Of course, while forming the conductive film 600 in Step (103), it is not necessary for the conductive film 600 to overlay the inner surface 310 of the first chassis 300 completely and exactly, in principle, the conductive film 600 including the bulge portions 610 will be considered not contacting any “non-grounded ” terminals (e.g. Vcc pin) of the component 910.

The terms “inner surface 310” and “outer surface 320” in the specification mentioned above needs to be distinguished in which the surfaces of the first chassis 300 which could be exposed outwards the first chassis 300 are called “outer surface 320”, otherwise, other surfaces of the first chassis 300 which could be hided inside the first chassis 300 are called “inner surface 310” when the first chassis 300 is assembled with other chassis together. For instance, the so-called “inner surface 310” might be a surface of the first chassis 300 opposite to the outer surface 320, or surfaces of a rib of the first chassis 300 extended towards a direction opposite to the outer surface 320, or even, surfaces of a flange extended towards a direction of the outer surface 320.

Although the present invention has been described with reference to the preferred embodiments thereof, it is apparent to those skilled in the art that a variety of modifications and changes may be made without departing from the scope of the present invention which is intended to be defined by the appended claims.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A method of preparing conductive gaskets on a chassis, the method comprising:
providing a chassis having an inner surface thereon;
fixing an elastic block on the inner surface of the chassis; and
forming a conductive film on the inner surface of the chassis, wherein the conductive film is overlaid on both the elastic block and the inner surface of the chassis.

2. The method of preparing conductive gaskets on a chassis according to claim 1, wherein forming the conductive film on the inner surface of the chassis comprises:
by an electroplating means, depositing a plurality of metal ions with conductive properties on surfaces of the elastic block and the inner surface of the chassis so as to integrate into the conductive film.

3. The method of preparing conductive gaskets on a chassis according to claim 2, wherein the metal ions are deposited on surfaces of the elastic block which are not contacted with the inner surface of the chassis.

4. The method of preparing conductive gaskets on a chassis according to claim 2, wherein some of the metal ions are penetrated through the elastic block to dispose on a section of the inner surface which is contacted by the elastic block.

5. The method of preparing conductive gaskets on a chassis according to claim 2, wherein the electroplating means comprises a method of plastic plating, vacuum plating, composite plating electroless plating, spray plating, immersion plating or plasma plating.

6. The method of preparing conductive gaskets on a chassis according to claim 1, wherein the material of the conductive film is selected from the group consisting of aluminum, nickel, copper, chromium, tin, titanium, stainless steel and the combination thereof.

7. The method of preparing conductive gaskets on a chassis according to claim 1, wherein forming the conductive film on the inner surface of the chassis comprises:
by a sputtering deposition means, depositing a plurality of metal ions with conductive properties on surfaces of the elastic block and the inner surface of the chassis so as to integrate into the conductive film.

8. The method of preparing conductive gaskets on a chassis according to claim 1, wherein the elastic block is made of plastic, rubber, cloth, leather or paper, and a compression ratio of the elastic block is in a range of 20%-30%.

9. A chassis with conductive gaskets, comprising:
a casing having an inner surface thereon;
a conductive film overlaid on the inner surface of the casing, and having at least one bulge portion thereon; and
at least one elastic block disposed on the inner surface of the casing, and covered in the bulge portion, wherein the elastic block has a shape same as the bulge portion.

10. The chassis with conductive gaskets according to claim 9, wherein the bulge portion of the conductive film covers surfaces of the elastic block which are not contacted with the inner surface of the casing.

11. The chassis with conductive gaskets according to claim 9, wherein the bulge portion of the conductive film covers all surfaces of the elastic block.

12. The chassis with conductive gaskets according to claim 9, wherein the elastic block is made of plastic, rubber, cloth, leather or paper, and a compression ratio of the elastic block is in a range of 20%-30%.

13. The chassis with conductive gaskets according to claim 9, wherein the material of the conductive film is selected from the group consisting of aluminum, nickel, copper, chromium, tin, titanium, stainless steel and the combination thereof.

14. A method of assembling an electric device, comprising:
providing a first chassis;
fixing an elastic block on an inner surface of the first chassis;
coating a conductive film on the inner surface of the first chassis, wherein the conductive film is overlaid on both the elastic block and the inner surface of the first chassis;
providing a second chassis and a motherboard, wherein the motherboard is with a component thereon; and
assembling the first chassis and the second chassis together, wherein the motherboard is sandwiched between the first chassis and the second chassis, and an section of the conductive film corresponding to the elastic block contacts with a grounding portion of the component, and the conductive film is electrically conducted to a grounding of the electric device.
